(19) United States
(12) Patent Application Publication
(10) Pub. No.: US 2024/0145224 A1
(43) Pub. Date: May 2, 2024

(54) POWER SUPPLY SYSTEMS AND METHODS

(71) Applicant: Micromass UK Limited, Wilmslow (GB)

(72) Inventors: Thomas Moore, Wilmslow (GB); Richard McClelland, Wilmslow (GB)

(73) Assignee: Micromass UK Limited, Wilmslow (GB)

(21) Appl. No.: 18/546,010

(22) PCT Filed: Jan. 21, 2022
(86) PCT No.: PCT/GB2022/050165

§ 371 Date: Aug. 10, 2023

(30) Foreign Application Priority Data
Feb. 11, 2021 (GB) 2101918.7

(51) Int. Cl. H01J 49/02; H01J 49/26; H02M 1/00; H03K 17/042; H03K 17/78

(52) U.S. Cl. CPC H01J 49/022; H02M 1/0003; H03K 17/042; H03K 17/78; H01J 49/26; H03K 2217/0027

(57) ABSTRACT

Power supply systems and methods A power supply system (1) for a mass spectrometer. The system (1) comprises first and second optocouplers (19, 20) which are controlled by a controller (3). The controller (3) is configured to operate in at least one of three control modes to control the optocouplers (19, 20) to deliver a system output signal to a component (7) of a mass spectrometer.

### FIELD

The present invention relates to a power supply system for a mass spectrometer and a method of operating such a power supply system. The present invention more particularly relates to a high voltage power supply system suitable for providing power to a mass spectrometer.

### BACKGROUND

A mass spectrometer requires a high voltage or high tension power supply to operate. The power supply must be capable of delivering several thousand volts, for instance for use in an electrospray ionisation source.

In order to meet the requirements of voltage, switching speed and supply current for a power supply for mass spectrometry, conventional power supplies typically incorporate conventional power supply switching circuitry. This conventional power supply switching circuitry is typically bulky and is therefore undesirable in a mass spectrometer.

There is a need for an improved power supply system for a mass spectrometer and a method of operating such a power supply system which alleviates at least some of the problems outlined herein.

The present invention seeks to provide an improved power supply system for a mass spectrometer and an improved method of operating such a power supply system.

### SUMMARY

According to one aspect of the present invention, there is provided a power supply system for a mass spectrometer, the system comprising: a system output terminal for delivering a system output signal to a component of a mass spectrometer; a positive voltage terminal which is configured to provide a positive supply voltage; a negative voltage terminal which is configured to provide a negative supply voltage; a first optocoupler which is configured to couple the positive voltage terminal to the system output terminal electrically by a variable electrical conductance which is set in response to a first control signal; a second optocoupler which is configured to couple the negative voltage terminal to the system output terminal electrically by a variable electrical conductance which is set in response to a second control signal; and a controller which is configured to operate in at least one of: a first control mode in which the controller is configured to: provide the first control signal to the first optocoupler and the second control signal to the second optocoupler alternately such that the system output terminal delivers a system output signal which switches alternately between the positive supply voltage and the negative supply voltage; a second control mode in which the controller is configured to: provide the first control signal to the first optocoupler; receive a positive voltage feedback signal indicative of the positive supply voltage; provide the second control signal to the second optocoupler; receive a negative voltage feedback signal indicative of the negative supply voltage; and adjust at least one of the first control signal or the second control to set the electrical conductance of the first optocoupler and the electrical conductance of the second optocoupler respectively such that the system output terminal delivers a system output signal having a voltage between the positive supply voltage and the negative supply voltage; or a third control mode in which the controller is configured to: provide the first control signal to the first optocoupler; provide the second control signal to the second optocoupler; receive a current feedback signal which is indicative of a current output flowing from the system output terminal; and adjust at least one of the first control signal or the second control to set the electrical conductance of the first optocoupler and the electrical conductance of the second optocoupler respectively such that the system output terminal delivers a constant current output.

In some examples, the system further comprises: a first power supply having a first output which is coupled electrically to the positive voltage terminal and a second output which is a return output; a second power supply having a third output which is a return output and a fourth output which is coupled electrically to the negative voltage terminal, wherein the second and third outputs of the first and second power supplies are coupled electrically to one another by a return path.

In some examples, the first power supply is configured to provide a positive voltage of between +1 kV and +15 kV at the positive voltage terminal; and the second power supply is configured to provide a negative voltage of between −1 kV and −15 kV at the negative voltage terminal.

In some examples, the system further comprises: a current sensing arrangement which is coupled electrically to the return path to sense a current flowing along the return path, wherein the current sensing arrangement is configured to provide the current feedback signal to the controller, the current feedback signal being proportional to a current flowing along the return path.

In some examples, the current sensing arrangement is a bidirectional current sensing arrangement which is configured to sense current flow in either direction along the return path.

In some examples, the system further comprises: a system output feedback path which provides a feedback path between the system output terminal and the controller.

In some examples, the system further comprises: a positive voltage feedback path which provides a feedback path between the positive voltage terminal and the controller.

In some examples, the system further comprises: a negative voltage feedback path which provides a feedback path between the negative voltage terminal and the controller.

In some examples, the system further comprises: a first capacitor which is coupled electrically between the positive voltage terminal and ground.

In some examples, the system further comprises: a second capacitor which is coupled electrically between the negative voltage terminal and ground.

In some examples, each optocoupler has a maximum voltage rating of between 10 kV and 25 kV.

In some examples, each optocoupler comprises: a control terminal which is coupled electrically to the controller to receive a control signal; a light transmitter which is configured to transmit light in response to a control signal from the controller; first and second output terminals, wherein one output terminal is coupled electrically to one of the positive voltage terminal and the system output terminal and the other output terminal is coupled electrically to one of the system output terminal and the negative voltage terminal; and a light sensitive semiconductor which is coupled electrically between the first and second output terminals, the light sensitive semiconductor having an electrical conductance which varies depending upon the intensity of light transmitted from the light transmitter onto the light sensitive semiconductor.

According to another aspect of the present invention, there is provided a mass spectrometer comprising the system of any one the claims as defined hereinafter, wherein the mass spectrometer comprises a power input terminal which is coupled electrically to the system output terminal.

According to a further aspect of the present invention, there is provided a method of operating a power supply system for a mass spectrometer, the power supply system comprising: a system output terminal for delivering a system output signal to a component of a mass spectrometer; a positive voltage terminal which is configured to provide a positive supply voltage; a negative voltage terminal which is configured to provide a negative supply voltage; a first optocoupler which is configured to couple the positive voltage terminal to the system output terminal electrically by a variable electrical conductance which is set in response to a first control signal; a second optocoupler which is configured to couple the negative voltage terminal to the system output terminal electrically by a variable electrical conductance which is set in response to a second control signal; and a controller, wherein the method comprises controlling the controller to operate in at least one of: a first control mode in which the controller: provides the first control signal to the first optocoupler and the second control signal to the second optocoupler alternately such that the system output terminal delivers a system output signal which switches alternately between the positive supply voltage and the negative supply voltage; a second control mode in which the controller: provides the first control signal to the first optocoupler; receives a positive voltage feedback signal indicative of the positive supply voltage; provides the second control signal to the second optocoupler; receives a negative voltage feedback signal indicative of the negative supply voltage; and adjusts at least one of the first control signal or the second control to set the electrical conductance of the first optocoupler and the electrical conductance of the second optocoupler respectively such that the system output terminal delivers a system output signal having a voltage between the positive supply voltage and the negative supply voltage; or a third control mode in which the controller: provides the first control signal to the first optocoupler; provides the second control signal to the second optocoupler; receives a current feedback signal which is indicative of a current output flowing from the system output terminal; and adjusts at least one of the first control signal or the second control to set the electrical conductance of the first optocoupler and the electrical conductance of the second optocoupler respectively such that the system output terminal delivers a constant current output.

### BRIEF DESCRIPTION OF THE DRAWINGS

So that the present invention may be more readily understood, embodiments of the present invention will now be described, by way of example, with reference to the accompanying drawings, in which:

FIG. 1 is a schematic diagram of an example power supply system of this disclosure coupled to a mass spectrometer,

FIG. 2 is a circuit diagram of an example power supply system of this disclosure, and

FIG. 3 is a perspective view of part of an example power supply system of this disclosure.

### DETAILED DESCRIPTION

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

The following disclosure provides many different embodiments, or examples, for implementing different features of the provided subject matter. Specific examples of components, concentrations, applications and arrangements are described below to simplify the present disclosure. These are, of course, merely examples and are not intended to be limiting. For example, the attachment of a first feature and a second feature in the description that follows may include embodiments in which the first feature and the second feature are attached in direct contact, and may also include embodiments in which additional features may be positioned between the first feature and the second feature, such that the first feature and the second feature may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The following disclosure describes representative examples. Each example may be considered to be an embodiment and any reference to an “example” may be changed to “embodiment” in the present disclosure.

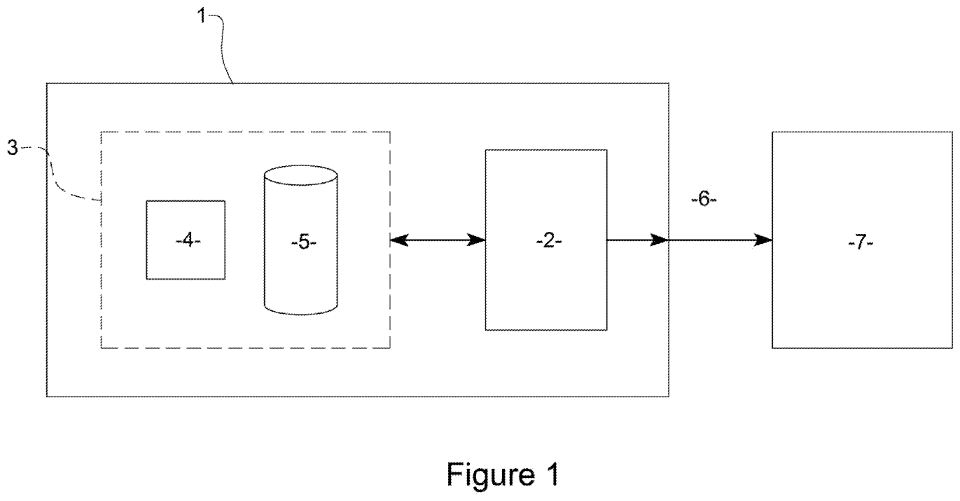

Referring initially to FIG. 1 of the accompanying drawings, a power supply system 1 of some examples comprises a power supply arrangement 2 and a controller 3. The power supply arrangement 2 is configured to receive power from an external power source (not shown), such as a mains power source. The power supply arrangement 2 is configured to be controlled by the controller 3. The controller 3 comprises a processor 4 and a memory 5 which are coupled to one another to form a computing device. The memory 5 stores executable instructions which, when executed by the processor 4, cause the processor 4 to perform various functions of the controller 3.

The power supply system 1 comprises a system output terminal 6 for delivering a system output signal to a component 7 of a mass spectrometer. In FIG. 1, the system output terminal 6 is shown coupled electrically to a component 7 of a mass spectrometer. The component 7 may be any component of a mass spectrometer which is suitable to receive power from the power supply system 1.

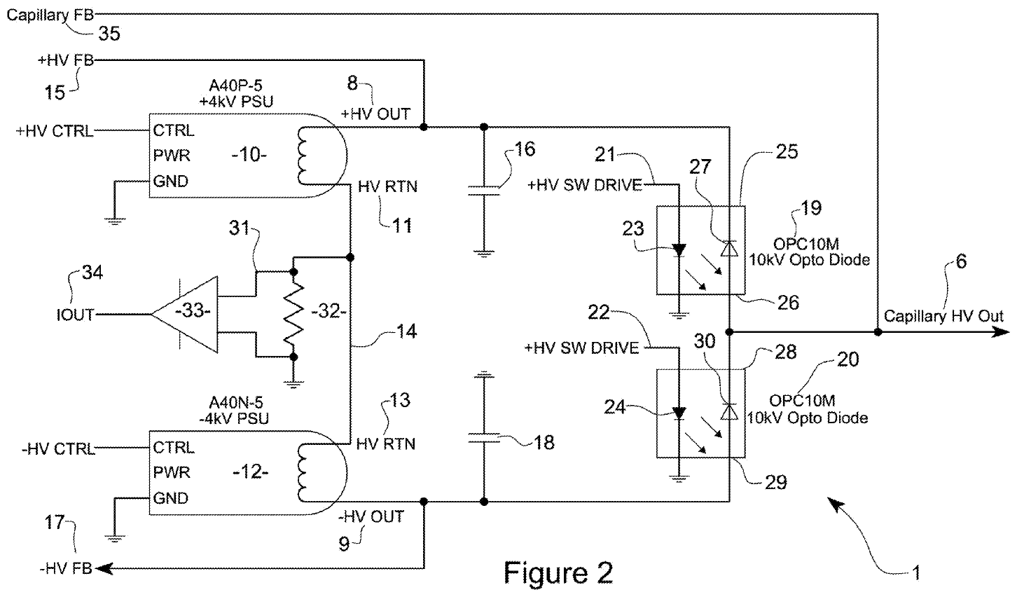

Referring now to FIG. 2 of the accompanying drawings, the power supply system 1 comprises a positive voltage terminal 8 which is configured to provide a positive supply voltage and a negative voltage terminal 9 which is configured to provide a negative supply voltage.

In this representative example, the power supply system 1 comprises a first power supply 10 having a first output which is coupled electrically to the positive voltage terminal 8 and a second output 11 which is a return output. The system 1 comprises a second power supply 12 having a third output 13 which is a return output and a fourth output which is coupled electrically to the negative voltage terminal 9. The second and third outputs 11, 13 of the first and second power supplies 10, 12 are coupled electrically to one another by a return path 14.

In some examples, the first power supply 10 is a high voltage power supply which is configured to provide a positive voltage of between +1 kV and +15 kV at the positive voltage terminal 8. In some examples, a positive voltage feedback path 15 provides a feedback path between the positive voltage terminal 8 and the controller 3. In some examples, a first capacitor 16 is coupled electrically between the positive voltage terminal 8 and ground.

In some examples, the second power supply 12 is a high voltage power supply which is configured to provide a negative voltage of between −1 kV and −15 kV at the negative voltage terminal 9. In some examples, a negative voltage feedback path 17 provides a feedback path between the negative voltage terminal 9 and the controller 3. In some examples, a second capacitor 18 is coupled electrically between the negative voltage terminal 9 and ground.

The power supply system 1 comprises a first optocoupler 19 and a second optocoupler 20. In this example, the first and second optocouplers 19, 20 are identical to one another but in other examples the optocouplers 19, 20 may be different. Each optocoupler is a high voltage optocoupler. In some examples, each optocoupler is a high voltage optocoupler which has a maximum voltage rating of between 10 kV and 25 kV.

Each optocoupler 19, 20 comprises a respective control terminal 21, 22 which is coupled electrically to the controller 3 to receive a respective control signal. Each optocoupler 19, 20 comprises a respective light transmitter 23, 24 which is coupled between the control terminal 21, 22 and ground and configured to transmit light in response to a respective control signal from the controller 3.

The control signals provided by the controller 3 to the first and second optocouplers 19, 20 are signals which control the light transmitters 23, 24 to transmit light at intensities which are proportional to the control signals. For instance, in some examples, the control signals are control currents which are set by the controller 3 which drive the light transmitters 23, 24 to transmit light at intensities which are proportional to the control currents.

The first optocoupler 19 comprises respective first and second output terminals 25, 26. The first output terminal 25 is coupled electrically to the positive voltage terminal 8 and the second output terminal 26 is coupled electrically to the system output terminal 6.

The first optocoupler 19 comprises a first light sensitive semiconductor 27, such as a photodiode, which is coupled electrically between the first and second output terminals 25, 26. The first light sensitive semiconductor 27 has an electrical conductance which varies depending upon the intensity of light transmitted from the light transmitter 23 onto the first light sensitive semiconductor 27. The first optocoupler 19 is thus configured to couple the positive voltage terminal 8 to the system output terminal 6 electrically by a variable electrical conductance which is set in response to a first control signal from the controller 3.

The second optocoupler 20 comprises respective first and second output terminals 28, 29. The second output terminal 29 is coupled electrically to the negative voltage terminal 9 and the first output terminal 28 is coupled electrically to the system output terminal 6.

The second optocoupler 19 comprises a second light sensitive semiconductor 30, such as a photodiode, which is coupled electrically between the first and second output terminals 28, 29. The second light sensitive semiconductor 30 has an electrical conductance which varies depending upon the intensity of light transmitted from the light transmitter 24 onto the second light sensitive semiconductor 30. The second optocoupler 20 is thus configured to couple the negative voltage terminal 9 to the system output terminal 6 electrically by a variable electrical conductance which is set in response to a second control signal from the controller 3.

Returning now to the first and second power supplies 10, 12, in some examples the system 1 comprises a current sensing arrangement 31 which is coupled electrically to the return path 14 to sense a current flowing along the return path 14. In this example, the current sensing arrangement 31 comprises a resistor 32 and an operational amplifier 33 which senses a current flowing through the resistor 32. The operational amplifier 33 has an output 34 which is coupled to the controller 3 to provide a current feedback signal to the controller 3 which is proportional to a current flowing along the return path 14.

It is to be appreciated that the current sensing arrangement 31 is one type of current sensing arrangement which is provided in this representative example. In other examples, the system 1 comprises an alternative current sensing arrangement which provides an equivalent function to the current sensing arrangement 31.

In some examples, the current sensing arrangement 31 is a bidirectional current sensing arrangement which is configured to sense current flow in either direction along the return path 14.

In a further example, the second and third outputs 11, 13 of the first and second power supplies 10, 12 are not directly coupled electrically to one another but are instead coupled to Common ground. In this further example, separate current sensing arrangements are coupled respectively to the second and third outputs 11, 13 of the first and second power supplies 10, 12, to sense current flow in each return path individually.

In some examples, the system 1 comprises a system output feedback path which provides a feedback path 35 between the system output terminal 6 and the controller 3.

Returning now to the controller 3, the controller 3 is configured to operate in at least one of three different operating modes which are described below. The controller 3 selects the control mode which provides an appropriate output from the system output terminal 6 for driving a component 7 of a mass spectrometer. The configuration of the controller 3 is, in some examples, carried out in response to a separate controller, such as a central control unit within a mass spectrometer.

In some examples, the controller 3 is a microcontroller or other form of computing device. In other examples, the controller 3 is an analogue controller consisting of analogue components coupled together to form an analogue control circuit. In further embodiments, the controller 3 comprises both an analogue control circuit and a digital controller, such as a microcontroller, which operate in conjunction with one another.

### First Control Mode

A first control mode of the controller 3 provides a form of digital voltage control. In the first control mode, the controller 3 controls the optocouplers 19, 20 such that the system output terminal delivers 6 a system output signal which switches alternately between the positive supply voltage supplied by the first power supply 10 and the negative supply voltage supplied by the second power supply 12. The controller 3 achieves the first control mode by providing a first control signal to the first optocoupler 19 and a second control signal to the second optocoupler 20 alternately. The first and second optocouplers 19, switch on and off alternately in response to the first and second control signals.

### Second Control Mode

A second control mode of the controller 3 provides a form of analogue voltage control. In the second control mode, the controller 3 provides a first control signal to the first optocoupler 19 and a second control signal to the second optocoupler 20. The controller 3 receives a positive voltage feedback signal via the positive voltage feedback path 15 which is indicative of the positive supply voltage supplied by the first power supply 10. The controller 3 also receives a negative voltage feedback signal via the negative voltage feedback path 17 which is indicative of the negative supply voltage supplied by the second power supply 12.

The controller 3 adjusts at least one of the first control signal or the second control to vary the intensity of light transmitted by the light transmitters 23, 24 which, in turn sets the electrical conductance of the first and second optocouplers 19, 20. This analogue control of the optocouplers allows the system output terminal 6 to deliver a system output signal having a voltage between the positive supply voltage and the negative supply voltage. The voltage of the system output signal is thus selected by the controller 3 in this second control mode.

### Third Control Mode

A third control mode of the controller 3 provides a form of current mode control. In the third control mode, the controller 3 provides a first control signal to the first optocoupler 19 and a second control signal to the second optocoupler 20. The controller 3 receives a current feedback signal via the output 34 of the current sensing arrangement 31 which is indicative of a current output flowing from the system output terminal 6.

The controller 3 adjusts at least one of the first control signal or the second control to vary the intensity of light transmitted by the light transmitters 23, 24 which, in turn sets the electrical conductance of the first and second optocouplers 19, 20. The controller 3 controls the first and second optocouplers 19, 20 in this way such that the system output terminal 6 delivers a constant current output.

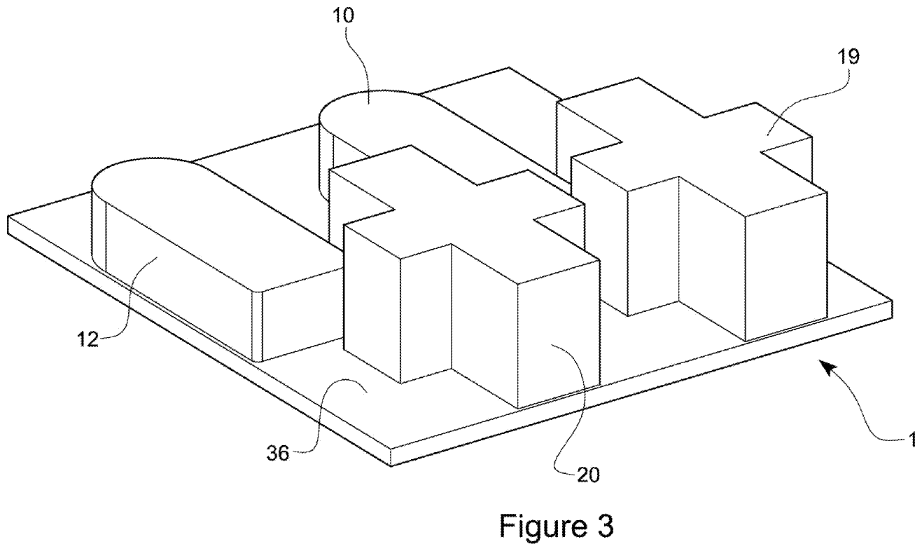

Referring now to FIG. 3 of the accompanying drawings, in some examples the various components of the power supply system are mounted on a printed circuit board (PCB) 36. In the example shown in FIG. 3, the PCB 36 is 58 mm long and 51 mm wide. The compact size is achieved through the use of the optocouplers 19, 20 which are more compact than conventional switching components in a power supply system. In some examples, the power supply system 1 is small enough to fit within a source corner module of a mass spectrometer, which is typically empty with the space being wasted in a conventional mass spectrometer.

While the examples described above comprise two optocouplers and two power supplies, it is to be appreciated that in other examples the system comprises a greater number of optocouplers and/or power supplies. In some examples, the system comprises more than two optocouplers which are configured to be controlled by the controller 3 to drive a plurality of outputs from the same voltage terminals 8, 9. In other examples, the system comprises more than two power supplies which are each controlled by the controller 3 and which each output a respective independent voltage.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described features (e.g., elements, resources, etc.), the terms used to describe such features are intended to correspond, unless otherwise indicated, to any features which performs the specified function of the described features (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

Embodiments of the subject matter and the functional operations described herein can be implemented in analogue electronic circuitry, digital electronic circuitry, a mixture of analogue and digital circuitry, or in computer software, firmware, or hardware, including the structures disclosed in this specification and their structural equivalents, or in combinations of one or more of them.

Features of some embodiments are implemented using one or more modules of computer program instructions encoded on a computer-readable medium for execution by, or to control the operation of, a data processing apparatus or a controller. The computer-readable medium can be a manufactured product, such as hard drive in a computer system or an embedded system. The computer-readable medium can be acquired separately and later encoded with the one or more modules of computer program instructions, such as by delivery of the one or more modules of computer program instructions over a wired or wireless network. The computer-readable medium can be a machine-readable storage device, a machine-readable storage substrate, a memory device, or a combination of one or more of them.

The terms “computing device” and “data processing apparatus” encompass all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, a runtime environment, or a combination of one or more of them. In addition, the apparatus can employ various different computing model infrastructures, such as web services, distributed computing and grid computing infrastructures.

The processes and logic flows described in this specification can be performed by one or more programmable processors executing one or more computer programs to perform functions by operating on input data and generating output.

As used herein, in some embodiments the term module comprises a memory and/or a processor configured to control at least one process of a system or a circuit structure. The memory storing executable instructions which, when executed by the processor, cause the processor to provide an output to perform the at least one process. Embodiments of the memory include non-transitory computer readable media.

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Devices suitable for storing computer program instructions and data include all forms of non-volatile memory, media and memory devices.

In the present specification “comprise” means “includes or consists of” and “comprising” means “including or consisting of”.

When used in this specification and claims, the terms “comprises” and “comprising” and variations thereof mean that the specified features, steps or integers are included. The terms are not to be interpreted to exclude the presence of other features, steps or components.

The features disclosed in the foregoing description, or the following claims, or the accompanying drawings, expressed in their specific forms or in terms of a means for performing the disclosed function, or a method or process for attaining the disclosed result, as appropriate, may, separately, or in any combination of such features, be utilised for realising the invention in diverse forms thereof.

Although certain example embodiments of the invention have been described, the scope of the appended claims is not intended to be limited solely to these embodiments. The claims are to be construed literally, purposively, and/or to encompass equivalents.

1. A power supply system for a mass spectrometer, the system comprising:
a system output terminal for delivering a system output signal to a component of a mass spectrometer;
a positive voltage terminal which is configured to provide a positive supply voltage;
a negative voltage terminal which is configured to provide a negative supply voltage;
a first optocoupler which is configured to couple the positive voltage terminal to the system output terminal electrically by a variable electrical conductance which is set in response to a first control signal;
a second optocoupler which is configured to couple the negative voltage terminal to the system output terminal electrically by a variable electrical conductance which is set in response to a second control signal; and
a controller which is configured to operate in at least one of:
a first control mode in which the controller is configured to:
provide the first control signal to the first optocoupler and the second control signal to the second optocoupler alternately such that the system output terminal delivers a system output signal which switches alternately between the positive supply voltage and the negative supply voltage;
a second control mode in which the controller is configured to:
provide the first control signal to the first optocoupler;
receive a positive voltage feedback signal indicative of the positive supply voltage;
provide the second control signal to the second optocoupler;
receive a negative voltage feedback signal indicative of the negative supply voltage; and
adjust at least one of the first control signal or the second control to set the electrical conductance of the first optocoupler and the electrical conductance of the second optocoupler respectively such that the system output terminal delivers a system output signal having a voltage between the positive supply voltage and the negative supply voltage; or
a third control mode in which the controller is configured to:
provide the first control signal to the first optocoupler;
provide the second control signal to the second optocoupler;
receive a current feedback signal which is indicative of a current output flowing from the system output terminal; and
adjust at least one of the first control signal or the second control to set the electrical conductance of the first optocoupler and the electrical conductance of the second optocoupler respectively such that the system output terminal delivers a constant current output.

2. The system of claim 1, wherein the system further comprises:
a first power supply having a first output which is coupled electrically to the positive voltage terminal and a second output which is a return output;
a second power supply having a third output which is a return output and a fourth output which is coupled electrically to the negative voltage terminal, wherein the second and third outputs of the first and second power supplies are coupled electrically to one another by a return path.

3. The system of claim 2, wherein:
the first power supply is configured to provide a positive voltage of between +1 kV and +15 kV at the positive voltage terminal; and
the second power supply is configured to provide a negative voltage of between −1 kV and −15 kV at the negative voltage terminal.

4. The system of claim 2, wherein the system further comprises:
a current sensing arrangement which is coupled electrically to the return path to sense a current flowing along the return path, wherein the current sensing arrangement is configured to provide the current feedback signal to the controller, the current feedback signal being proportional to a current flowing along the return path.

5. The system of claim 4, wherein the current sensing arrangement is a bidirectional current sensing arrangement which is configured to sense current flow in either direction along the return path.

6. The system of claim 1, wherein the system further comprises:
a system output feedback path which provides a feedback path between the system output terminal and the controller.

7. The system of claim 1, wherein the system further comprises:
a positive voltage feedback path which provides a feedback path between the positive voltage terminal and the controller.

8. The system of claim 1, wherein the system further comprises:
a negative voltage feedback path which provides a feedback path between the negative voltage terminal and the controller.

9. The system of claim 1, wherein the system further comprises:
a first capacitor which is coupled electrically between the positive voltage terminal and ground.

10. The system of claim 1, wherein the system further comprises:
a second capacitor which is coupled electrically between the negative voltage terminal and ground.

11. The system of claim 1, wherein each optocoupler has a maximum voltage rating of between 10 kV and 25 kV.

12. The system of claim 1, wherein each optocoupler comprises:
a control terminal which is coupled electrically to the controller to receive a control signal;
a light transmitter which is configured to transmit light in response to a control signal from the controller;
first and second output terminals, wherein one output terminal is coupled electrically to one of the positive voltage terminal and the system output terminal and the other output terminal is coupled electrically to one of the system output terminal and the negative voltage terminal; and
a light sensitive semiconductor which is coupled electrically between the first and second output terminals, the light sensitive semiconductor having an electrical conductance which varies depending upon the intensity of light transmitted from the light transmitter onto the light sensitive semiconductor.

13. A mass spectrometer comprising:
a power input terminal; and
a power supply system comprising:
a system output terminal coupled electrically to the power input terminal for delivering a system output signal to a component of the mass spectrometer;
a positive voltage terminal which is configured to provide a positive supply voltage;
a negative voltage terminal which is configured to provide a negative supply voltage;
a first optocoupler which is configured to couple the positive voltage terminal to the system output terminal electrically by a variable electrical conductance which is set in response to a first control signal;
a second optocoupler which is configured to couple the negative voltage terminal to the system output terminal electrically by a variable electrical conductance which is set in response to a second control signal; and
a controller which is configured to operate in at least one of:
a first control mode in which the controller is configured to:
provide the first control signal to the first optocoupler and the second control signal to the second optocoupler alternately such that the system output terminal delivers a system output signal which switches alternately between the positive supply voltage and the negative supply voltage;
a second control mode in which the controller is configured to:
provide the first control signal to the first optocoupler;
receive a positive voltage feedback signal indicative of the positive supply voltage;
provide the second control signal to the second optocoupler;
receive a negative voltage feedback signal indicative of the negative supply voltage; and
adjust at least one of the first control signal or the second control to set the electrical conductance of the first optocoupler and the electrical conductance of the second optocoupler respectively such that the system output terminal delivers a system output signal having a voltage between the positive supply voltage and the negative supply voltage; or
a third control mode in which the controller is configured to:
provide the first control signal to the first optocoupler;
provide the second control signal to the second optocoupler;
receive a current feedback signal which is indicative of a current output flowing from the system output terminal; and
adjust at least one of the first control signal or the second control to set the electrical conductance of the first optocoupler and the electrical conductance of the second optocoupler respectively such that the system output terminal delivers a constant current output.

14. A method of operating a power supply system for a mass spectrometer, the power supply system comprising:
a system output terminal for delivering a system output signal to a component of a mass spectrometer;
a positive voltage terminal which is configured to provide a positive supply voltage;
a negative voltage terminal which is configured to provide a negative supply voltage;
a first optocoupler which is configured to couple the positive voltage terminal to the system output terminal electrically by a variable electrical conductance which is set in response to a first control signal;
a second optocoupler which is configured to couple the negative voltage terminal to the system output terminal electrically by a variable electrical conductance which is set in response to a second control signal; and
a controller, wherein the method comprises controlling the controller to operate in at least one of:
a first control mode in which the controller:
provides the first control signal to the first optocoupler and the second control signal to the second optocoupler alternately such that the system output terminal delivers a system output signal which switches alternately between the positive supply voltage and the negative supply voltage;
a second control mode in which the controller:
provides the first control signal to the first optocoupler;
receives a positive voltage feedback signal indicative of the positive supply voltage;
provides the second control signal to the second optocoupler;
receives a negative voltage feedback signal indicative of the negative supply voltage; and
adjusts at least one of the first control signal or the second control to set the electrical conductance of the first optocoupler and the electrical conductance of the second optocoupler respectively such that the system output terminal delivers a system output signal having a voltage between the positive supply voltage and the negative supply voltage; or
a third control mode in which the controller:
provides the first control signal to the first optocoupler;
provides the second control signal to the second optocoupler;
receives a current feedback signal which is indicative of a current output flowing from the system output terminal; and
adjusts at least one of the first control signal or the second control to set the electrical conductance of the first optocoupler and the electrical conductance of the second optocoupler respectively such that the system output terminal delivers a constant current output.
